(19) United States
(12) Patent Application Publication
(10) Pub. No.: US 2024/0268020 A1
(43) Pub. Date: Aug. 8, 2024

(54) COMPOSITION, CIRCUIT BOARD, AND METHOD FOR PRODUCING COMPOSITION

(71) Applicant: DAIKIN INDUSTRIES, LTD., Osaka (JP)

(72) Inventors: Kyouhei SAWAKI, Osaka (JP); Yuki UEDA, Osaka (JP); Shingo OKUNO, Osaka (JP); Mayuko TATEMICHI, Osaka (JP)

(73) Assignee: DAIKIN INDUSTRIES, LTD., Osaka (JP)

(21) Appl. No.: 18/630,293

(22) Filed: Apr. 9, 2024

Related U.S. Application Data
(63) Continuation of application No. PCT/JP2022/040021, filed on Oct. 26, 2022.

(30) Foreign Application Priority Data
Oct. 27, 2021 (JP) 2021-175703

(51) Int. Cl. H05K 1/03; H01B 1/02; H01B 3/44; H05K 1/09

(52) U.S. Cl. CPC H05K 1/0373; H01B 1/02; H01B 3/445; H05K 1/09

(57) ABSTRACT

The disclosure aims to provide a composition having excellent UV laser processibility and good electric properties, a circuit board, and a method for producing a composition. The composition contains a perfluorinated fluororesin and zinc oxide.

### CROSS-REFERENCE TO RELATED APPLICATIONS

This is a Rule 53(b) Continuation of International Application No. PCT/JP2022/040021 filed Oct. 26, 2022, claiming priority based on Japanese Patent Application No. 2021-175703 filed Oct. 27, 2021, the disclosures of which are incorporated by reference herein in their respective entireties.

### TECHNICAL FIELD

The disclosure relates to compositions, circuit boards, and methods for producing a composition.

### BACKGROUND ART

Speeding up of communication generates a demand for low dielectric, low loss materials for circuit boards to be used in devices such as electrical devices, electronic devices, and communication devices. Fluororesins are examined as these materials, but fluororesins need improvement in that they are less likely to absorb ultraviolet rays and they have poor UV laser processibility.

Patent Literature 1 discloses a method in which titanium oxide, for example, is added to a fluororesin to improve the ultraviolet absorbency.

Patent Literature 2 discloses a method in which zinc oxide is added to a fluororesin to give a UV blocking function.

### CITATION LIST

### Patent Literature

Patent Literature 1: JP 2020-37662 A
Patent Literature 2: JP 5246619 B

### SUMMARY

The disclosure (1) relates to a composition containing: a perfluorinated fluororesin; and zinc oxide (hereinafter, also referred to as the “composition of the disclosure”).

### Advantageous Effects

The disclosure can provide a composition having excellent UV laser processibility and good electric properties, a circuit board, and a method for producing a composition.

### DESCRIPTION OF EMBODIMENTS

The “organic group” herein means a group containing at least one carbon atom or a group formed by removing one hydrogen atom from an organic compound.

Examples of this “organic group” include
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent,
a heteroaryl group optionally containing at least one substituent,
a cyano group,
a formyl group,
RaO—,
RaCO—,
RaSO₂—,
RaCOO—,
RaNRaCO—,
RaCONRa—,
RaOCO—,
RaOSO₂—, and
RaNRbSO₂—,
wherein
the Ra groups are each independently
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent, or
a heteroaryl group optionally containing at least one substituent,
the Rb groups are each independently H or an alkyl group optionally containing at least one substituent.

The organic group is preferably an alkyl group optionally containing at least one substituent.

The disclosure will be specifically described hereinbelow.

The composition of the disclosure contains a perfluorinated fluororesin and zinc oxide.

Owing to the presence of zinc oxide, the composition of the disclosure has excellent UV laser processibility while containing a perfluorinated fluororesin.

Adding a component such as titanium oxide, as disclosed in Patent Literature 1, may impair the electric properties of the perfluorinated fluororesin. In contrast, zinc oxide is advantageous in that it has less influence on the electric properties. This can lead to not only excellent UV laser processibility but also good electric properties, resulting in a composition suitable for boards such as a high frequency board. Although Patent Literature 2 discloses a fluororesin containing zinc oxide, the fluororesin of Patent Literature 2 is intended to be used for a film for agricultural green houses; the literature neither discloses evaluation in the electric properties nor suggests the aforementioned advantage.

Further, zinc oxide is resistant to heat and can be mixed with a fluororesin by melt kneading. Melt kneading allows zinc oxide to well disperse in a fluororesin, leading to much improved UV laser processibility.

Owing to the presence of a perfluorinated fluororesin, the composition of the disclosure has better electric properties than other fluororesins such as an ethylene/tetrafluoroethylene copolymer (ETFE).

The perfluorinated fluororesin is a copolymer containing as a main component a fluorine-containing monomer such as a perfluoromonomer, and is a fluororesin containing a very small number of hydrogen atoms bonded to a carbon atom in a repeating unit of the main chain. Portions other than the repeating unit of the main chain, such as an end structure, may contain a hydrogen atom bonded to a carbon atom. A monomer other than the fluorine-containing monomer may be copolymerized as long as the resin contains the fluorine-containing monomer in an amount of 90 mol % or more. The amount of the fluorine-containing monomer is preferably 95 mol % or more, more preferably 99 mol % or more, and may be 100 mol %.

The perfluorinated fluororesin used may be a polymer of tetrafluoroethylene (TFE), which is a perfluoromonomer, or a copolymer of TFE and a copolymerizable monomer copolymerizable with TFE, for example.

The “perfluoromonomer” herein means a monomer in which all hydrogen atoms bonded to any carbon atom are replaced by fluorine atoms.

The copolymerizable monomer may be any monomer copolymerizable with TFE and free from a hydrogen atom bonded to a carbon atom of the main chain. Examples thereof include fluorine-containing monomers such as hexafluoropropylene (HFP) and those to be described later, including a fluoroalkyl vinyl ether, a fluoroalkyl ethylene, a fluoromonomer represented by the formula (100) CH₂═CFRf¹⁰¹ (wherein Rf¹⁰¹ is a C1-C12 linear or branched fluoroalkyl group), and a fluoroalkyl allyl ether. Examples of the monomer other than the fluorine-containing monomers include itaconic anhydride, citraconic anhydride, 5-norbornene-2,3-dicarboxylic acid anhydride, and maleic anhydride. One of these copolymerizable monomers may be used alone or two or more thereof may be used in combination.

The fluoroalkyl vinyl ether preferably includes at least one selected from the group consisting of:
a fluoromonomer represented by the formula (110):

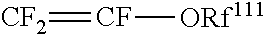

wherein Rf¹¹¹ is a perfluoro organic group;
a fluoromonomer represented by the formula (120):

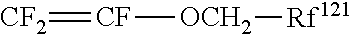

wherein Rf¹²¹ is a C1-C5 perfluoroalkyl group;
a fluoromonomer represented by the formula (130):

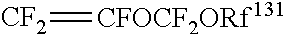

wherein Rf¹³¹ is a C1-C6 linear or branched perfluoroalkyl group, a C5-C6 cyclic perfluoroalkyl group, or a C2-C6 linear or branched perfluorooxyalkyl group containing one to three oxygen atoms;
a fluoromonomer represented by the formula (140):

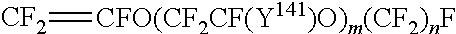

wherein Y¹⁴¹ is a fluorine atom or a trifluoromethyl group; m is an integer of 1 to 4; and n is an integer of 1 to 4; and
a fluoromonomer represented by the formula (150):

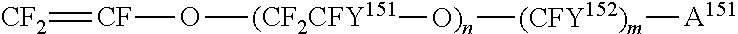

wherein Y¹⁵¹ is a fluorine atom, a chlorine atom, a —SO₂F group, or a perfluoroalkyl group, where the perfluoroalkyl group optionally contains ether oxygen and a —SO₂F group; n is an integer of 0 to 3; n Y¹⁵¹s are the same as or different from each other; Y¹⁵² is a fluorine atom, a chlorine atom, or a —SO₂F group; m is an integer of 1 to 5; m Y¹⁵²s are the same as or different from each other; and A¹⁵¹ is —SO₂X¹⁵¹, —COZ¹⁵¹, or —POZ¹⁵²Z¹⁵³, where X¹⁵¹ is F, Cl, Br, I, —OR¹⁵¹, or —NR¹⁵²R¹⁵³, and Z¹⁵¹, Z¹⁵², and Z¹⁵³ are the same as or different from each other and are each —NR¹⁵⁴R¹⁵⁵ or —OR¹⁵⁶, and where R¹⁵¹, R¹⁵², R¹⁵³, R¹⁵⁴, R¹⁵⁵, and R¹⁵⁶ are the same as or different from each other and are each H, ammonium, an alkali metal, or an alkyl group, aryl group, or sulfonyl-containing group optionally containing a fluorine atom.

The “perfluoro organic group” herein means an organic group in which all hydrogen atoms bonded to any carbon atom are replaced by fluorine atoms. The perfluoro organic group may have ether oxygen.

An example of the fluoromonomer represented by the formula (110) may be a fluoromonomer in which Rf¹¹¹ is a C1-C10 perfluoroalkyl group. The carbon number of the perfluoroalkyl group is preferably 1 to 5.

Examples of the perfluoro organic group in the formula (110) include a perfluoromethyl group, a perfluoroethyl group, a perfluoropropyl group, a perfluorobutyl group, a perfluoropentyl group, and a perfluorohexyl group.

Examples of the fluoromonomer represented by the formula (110) also include:
a monomer represented by the formula (110) in which Rf¹¹¹ is a C4-C9 perfluoro(alkoxyalkyl)group;
a monomer in which Rf¹¹¹ is a group represented by the following formula:

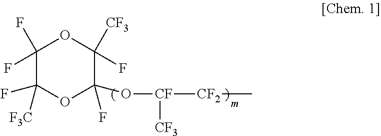

wherein m is 0 or an integer of 1 to 4; and
a monomer in which Rf¹¹¹ is a group represented by the following formula:

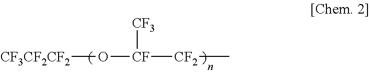

wherein n is an integer of 1 to 4.

In particular, the fluoromonomer represented by the formula (110) is preferably a perfluoro(alkyl vinyl ether) (PAVE), more preferably a fluoromonomer represented by the formula (160):

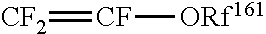

wherein Rf¹⁶¹ is a C1-C10 perfluoroalkyl group. Rf¹⁶¹ is preferably a C1-C5 perfluoroalkyl group.

The fluoroalkyl vinyl ether preferably includes at least one selected from the group consisting of fluoromonomers represented by any of the formulas (160), (130), and (140).

The fluoromonomer (PAVE) represented by the formula (160) preferably includes at least one selected from the group consisting of perfluoro(methyl vinyl ether) (PMVE), perfluoro(ethyl vinyl ether) (PEVE), and perfluoro(propyl vinyl ether) (PPVE), more preferably includes at least one selected from the group consisting of perfluoro(methyl vinyl ether) and perfluoro(propyl vinyl ether).

The fluoromonomer represented by the formula (130) preferably includes at least one selected from the group consisting of CF₂═CFOCF₂OCF₃, CF₂═CFOCF₂OCF₂CF₃, and CF₂═CFOCF₂OCF₂CF₂OCF₃.

The fluoromonomer represented by the formula (140) preferably includes at least one selected from the group consisting of CF₂═CFOCF₂CF(CF₃)O(CF₂)₃F, CF₂═CFO(CF₂CF(CF₃)O)₂(CF₂)₃F, and CF₂═CFO(CF₂CF(CF₃)O)₂ (CF₂)₂F.

The fluoromonomer represented by the formula (150) preferably includes at least one selected from the group consisting of CF₂═CFOCF₂CF₂SO₂F, CF₂═CFOCF₂CF(CF₃)OCF₂CF₂SO₂F, CF₂═CFOCF₂CF(CF₂CF₂SO₂F) OCF₂CF₂SO₂F, and CF₂═CFOCF₂CF(SO₂F)₂.

The fluoromonomer represented by the formula (100) is preferably a fluoromonomer in which Rf¹⁰¹ is a linear fluoroalkyl group, more preferably a fluoromonomer in which Rf¹⁰¹ is a linear perfluoroalkyl group. Rf¹⁰¹ preferably has a carbon number of 1 to 6. Examples of the fluoromonomer represented by the formula (100) include CH₂═CFCF₃, CH₂═CFCF₂CF₃, CH₂═CFCF₂CF₂CF₃, CH₂═CFCF₂CF₂CF₂H, CH₂═CFCF₂CF₂CF₂CF₃, CHF═CHCF₃ (E configuration), and CHF═CHCF₃ (Z configuration). Preferred among these is 2,3,3,3-tetrafluoropropylene represented by CH₂═CFCF₃.

The fluoroalkylethylene is preferably a fluoroalkylethylene represented by the formula (170):

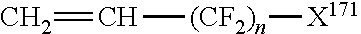

(wherein X¹⁷¹ is H or F; and n is an integer of 3 to 10);
and more preferably includes at least one selected from the group consisting of CH₂═CH—C₄F₉ and CH₂═CH—C₆F₁₃.

An example of the fluoroalkyl allyl ether may be a fluoromonomer represented by the formula (171):

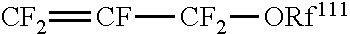

wherein Rf¹¹¹ is a perfluoro organic group.

Rf¹¹¹ in the formula (171) is defined as described for Rf¹¹¹ in the formula (110). Rf¹¹¹ is preferably a C1-C10 perfluoroalkyl group or a C1-C10 perfluoroalkoxyalkyl group. The fluoroalkyl allyl ether represented by the formula (171) preferably includes at least one selected from the group consisting of CF₂═CF—CF₂—O—CF₃, CF₂═CF—CF₂—O—C₂F₅, CF₂═CF—CF₂—O—C3F₇, and CF₂═CF—CF₂—O—C₄F₉, more preferably includes at least one selected from the group consisting of CF₂═CF—CF₂—O—C₂F₅, CF₂═CF—CF₂—O—C₃F₇, and CF₂═CF—CF₂—O—C₄F₉, and is still more preferably CF₂═CF—CF₂—O—CF₂CF₂CF₃.

To achieve less deformation and a lower linear expansion coefficient of the composition, the copolymerizable monomer is preferably a monomer containing a perfluorovinyl group, more preferably includes at least one selected from the group consisting of a perfluoro(alkyl vinyl ether) (PAVE), hexafluoropropylene (HFP), and perfluoroallyl ether, still more preferably includes at least one selected from the group consisting of PAVE and HFP. To reduce deformation of the composition during soldering, PAVE is particularly preferred.

The perfluorinated fluororesin preferably contains a unit of the copolymerizable monomer in a total amount of 0.1% by mass or more, more preferably 1.0% by mass or more, still more preferably 1.1% by mass or more of all monomer units. The total amount of the copolymerizable monomer unit is also preferably 30% by mass or less, more preferably 20% by mass or less, still more preferably 15% by mass or less of all monomer units.

The amount of the copolymerizable monomer unit is determined by ¹⁹F-NMR.

To achieve less deformation of the composition and a lower linear expansion coefficient of the composition, the perfluorinated fluororesin preferably includes at least one selected from the group consisting of polytetrafluoroethylene (PTFE), a tetrafluoroethylene (TFE)/perfluoro(alkyl vinyl)ether (PAVE) copolymer (PFA), and a tetrafluoroethylene (TFE)/hexafluoropropylene (HFP) copolymer (FEP), more preferably at least one selected from the group consisting of PFA and FEP, and is still more preferably PFA.

In the case where the perfluorinated fluororesin is PFA containing a TFE unit and a PAVE unit, the PAVE unit is preferably contained in an amount of 0.1 to 12% by mass of all polymerized units. The amount of the PAVE unit is more preferably 0.3% by mass or more, still more preferably 0.7% by mass or more, further preferably 1.0% by mass or more, particularly preferably 1.1% by mass or more, while more preferably 8.0% by mass or less, still more preferably 6.5% by mass or less, particularly preferably 6.0% by mass or less of all polymerized units.

The amount of the PAVE unit is determined by ¹⁹F-NMR.

In the case where the perfluorinated fluororesin is FEP containing a TFE unit and a HFP unit, the TFE unit and the HFP unit preferably have a mass ratio (TFE/HFP) of (70 to 99)/(1 to 30) (% by mass). The mass ratio (TFE/HFP) is more preferably (85 to 95)/(5 to 15) (% by mass).

The FEP contains the HFP unit in an amount of 1% by mass or more, preferably 1.1% by mass or more of all monomer units.

The FEP preferably contains a perfluoro(alkyl vinyl ether) (PAVE) unit as well as the TFE unit and the HFP unit.

Examples of the PAVE unit contained in the FEP include the same as the PAVE units to form the aforementioned PFA. Preferred among these is PPVE.

The aforementioned PFA contains no HFP unit and is therefore different from the FEP containing a PAVE unit in this respect.

In the case where the FEP contains a TFE unit, a HFP unit, and a PAVE unit, they preferably have a mass ratio (TFE/HFP/PAVE) of (70 to 99.8)/(0.1 to 25)/(0.1 to 25) (% by mass). The FEP having a mass ratio within this range can have excellent heat resistance and excellent chemical resistance.

The mass ratio (TFE/HFP/PAVE) is more preferably (75 to 98)/(1.0 to 15)/(1.0 to 10) (% by mass).

The FEP contains the HFP unit and the PAVE unit in a total amount of 1% by mass or more, preferably 1.1% by mass or more of all monomer units.

The FEP containing a TFE unit, a HFP unit, and a PAVE unit preferably contains the HFP unit in an amount of 25% by mass or less of all monomer units.

The HFP unit contained in an amount within this range can lead to a composition having excellent heat resistance.

The amount of the HFP unit is more preferably 20% by mass or less, still more preferably 18% by mass or less, particularly preferably 15% by mass or less. The amount of the HFP unit is also preferably 0.1% by mass or more, more preferably 1% by mass or more, particularly preferably 2% by mass or more.

The amount of the HFP unit can be determined by ¹⁹F-NMR.

The amount of the PAVE unit is more preferably 20% by mass or less, still more preferably 10% by mass or less, particularly preferably 3% by mass or less. The amount of the PAVE unit is also preferably 0.1% by mass or more, more preferably 1% by mass or more. The amount of the PAVE unit can be determined by ¹⁹F-NMR.

The FEP may further contain a different ethylenic monomer (a) unit.

The different ethylenic monomer (a) unit may be any monomer unit copolymerizable with TFE, HFP, and PAVE. Examples thereof include fluorine-containing ethylenic monomers such as vinyl fluoride (VF), vinylidene fluoride (VdF), and chlorotrifluoroethylene (CTFE), as well as non-fluorinated ethylenic monomers such as ethylene, propylene, and alkyl vinyl ethers.

In the case where the FEP contains a TFE unit, a HFP unit, a PAVE unit, and a different ethylenic monomer (α) unit, they preferably have a mass ratio (TFE/HFP/PAVE/different ethylenic monomer (α)) of (70 to 98)/(0.1 to 25)/(0.1 to 25)/(0.1 to 10) (% by mass).

The FEP contains the monomer units excluding the TFE unit in a total amount of 1% by mass or more, preferably 1.1% by mass or more of all monomer units.

The perfluorinated fluororesin also preferably includes the PFA and the FEP. In other words, the PFA and the FEP may be used as a mixture thereof. The PFA and the FEP preferably have a mass ratio (PFA/FEP) of 90/10 to 30/70, more preferably 90/10 to 50/50.

The PFA and the FEP each may be produced, for example, by a conventionally known method in which monomers to serve as the structural units and additives such as a polymerization initiator are mixed as appropriate, followed by emulsion polymerization or suspension polymerization.

The perfluorinated fluororesin may be the PTFE.

The PTFE may be modified polytetrafluoroethylene (hereinafter, also referred to as modified PTFE), or may be homo polytetrafluoroethylene (hereinafter, also referred to as homo PTFE), or may be a mixture of modified PTFE and homo PTFE. To maintain the moldability of polytetrafluoroethylene well, the high molecular weight PTFE contains modified PTFE in a proportion of 10% by weight or more and 98% by weight or less, more preferably 50% by weight or more and 95% by weight or less. The homo PTFE suitably used may be, but is not limited to, one disclosed in JP S53-60979 A, JP S57-135 A, JP S61-16907 A, JP S62-104816 A, JP S62-190206 A, JP S63-137906A, JP 2000-143727 A, JP 2002-201217 A, WO 2007/046345, WO 2007/119829, WO 2009/001894, WO 2010/113950, WO 2013/027850, or the like. Particularly preferred is homo PTFE having high stretchability disclosed in JP S57-135 A, JP S63-137906 A, JP 2000-143727 A, JP 2002-201217 A, WO 2007/046345, WO 2007/119829, WO 2010/113950, or the like.

The modified PTFE contains TFE and a monomer other than the TFE (hereinafter, referred to as a modified monomer). Examples of the modified PTFE include, but are not limited to, one uniformly modified with a modifying monomer, one modified in an early stage of the polymerization reaction, and one modified in an end stage of the polymerization reaction. The modified PTFE is preferably a TFE copolymer obtainable by polymerizing not only TFE but also a monomer other than the TFE in a trace amount within the range that does not significantly impair the properties of the TFE homopolymer. The modified PTFE suitably used may be, but is not limited to, one disclosed in JP S60-42446 A, JP S61-16907 A, JP S62-104816 A, JP S62-190206 A, JP S64-1711 A, JP H02-261810 A, JP H11-240917 A, JP H11-240918 A, WO 2003/033555, WO 2005/061567, WO 2007/005361, WO 2011/055824, WO 2013/027850, or the like. Particularly preferred is modified PTFE having high stretchability disclosed in JP S61-16907 A, JP S62-104816 A, JP S64-1711 A, JP H11-240917 A, WO 2003/033555, WO 2005/061567, WO 2007/005361, WO 2011/055824, or the like.

The modified PTFE contains a TFE unit based on TFE and a modifying monomer unit based on a modifying monomer. The modifying monomer unit is a portion of the molecular structure of the modified PTFE and is derived from a modifying monomer. The modified PTFE contains the modifying monomer unit in an amount of preferably 0.001 to 0.500% by weight, and preferably 0.01 to 0.30% by mass of all monomer units. The term “all monomer units” refers to all portions derived from any monomer in the molecular structure of the modified PTFE.

The modifying monomer may be any one copolymerizable with TFE, and examples thereof include perfluoroolefins such as hexafluoropropylene (HFP); chlorofluoroolefins such as chlorotrifluoroethylene (CTFE); hydrogen-containing fluoroolefins such as trifluoroethylene and vinylidene fluoride (VDF); perfluorovinyl ether; (perfluoroalkyl)ethylenes (PFAE); and ethylene. One modifying monomer may be used alone or two or more modifying monomers may be used in combination.

The perfluorovinyl ether may be, but is not limited to, an unsaturated perfluoro compound represented by the following formula (1):

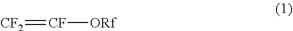

In the formula, Rf is a perfluoro organic group.

The perfluoro organic group herein means an organic group in which all hydrogen atoms bonded to any carbon atom are replaced by fluorine atoms. The perfluoro organic group may have ether oxygen.

An example of the perfluorovinyl ether is a perfluoro(alkyl vinyl ether) (PAVE) represented by the formula (1) wherein Rf is a C1-C10 perfluoroalkyl group. The carbon number of the perfluoroalkyl group is preferably 1 to 5. Examples of the perfluoroalkyl group in the PAVE include a perfluoromethyl group, a perfluoroethyl group, a perfluoropropyl group, a perfluorobutyl group, a perfluoropentyl group, and a perfluorohexyl group. The PAVE is preferably perfluoropropyl vinyl ether (PPVE) or perfluoromethyl vinyl ether (PMVE).

Examples of the (perfluoroalkyl)ethylene (PFAE) include, but are not limited to, (perfluorobutyl)ethylene (PFBE) and (perfluorohexyl)ethylene (PFHE).

The modifying monomer in the modified PTFE preferably includes at least one selected from the group consisting of HFP, CTFE, VDF, PAVE, PFAE, and ethylene.

The perfluorinated fluororesin is preferably non-melt-moldable. The term “non-melt-moldable” means that the resin does not exhibit sufficient fluidity when heated to a temperature equal to or higher than the melting point and thus cannot be molded by a melt-molding technique commonly used for resin. PTFE corresponds to this resin.

In the disclosure, preferably, a perfluorinated fluororesin that is non-melt-moldable as described above is used in a molding method in which this resin is formed into fibrils, forming a fluororesin sheet. This molding method will be described later.

The PTFE preferably has a SSG of 2.0 to 2.3. Using this PTFE can easily provide a PTFE film having high strength (high cohesive power and high puncture strength per unit thickness). Since PTFE having a high molecular weight has a long molecular chain, molecular chains thereof are less likely to form a regularly arranged structure. In this case, its amorphous portion has an increased length and the molecules entangle with each other at an increased degree. With the molecules entangled with each other at a high degree, the PTFE film seems to be less likely to deform against a load applied and to exhibit excellent mechanical strength. Using PTFE having a high molecular weight can also easily provide a PTFE film having a small average pore size.

The lower limit of the SSG is more preferably 2.05, still more preferably 2.1. The upper limit of the SSG is more preferably 2.25, still more preferably 2.2.

The standard specific gravity (SSG) is a specific gravity of a sample determined by water displacement, the sample being prepared in conformity with ASTM D4895-89.

In the present embodiment, the PTFE to form a PTFE powder has a molecular weight (number average molecular weight) within a range of 2000000 to 12000000, for example. The lower limit of the molecular weight of the PTFE may be 3000000 or may be 4000000. The upper limit of the molecular weight of the PTFE may be 10000000.

The number average molecular weight of the PTFE may be determined from the standard specific gravity or may be determined based on the dynamic viscoelasticity in a molten state. The determination method based on the standard specific gravity can be performed by the water displacement method in conformity with ASTM D792 using a sample formed in conformity with ASTM D4895-98. The determination method based on the dynamic viscoelasticity is described in, for example, S. Wu, Polymer Engineering & Science, 1988, Vol. 28, 538 and the same journal, 1989, Vol. 29, 273.

The PTFE preferably has a refractive index of 1.2 to 1.6. The PTFE having a refractive index in this range is preferred in that it can have low dielectricity. The refractive index can be adjusted to fall within this range by, for example, a method of adjusting the polarizabiilty or the flexibility of the main chain. The lower limit of the refractive index is more preferably 1.25, still more preferably 1.30, most preferably 1.32. The upper limit of the refractive index is more preferably 1.55, still more preferably 1.50, most preferably 1.45.

The refractive index is a value determined using a refractometer (Abbemat 300).

The PTFE preferably has a maximum endothermic peak temperature (crystalline melting point) of 340±7° C.

The PTFE may include a low melting point PTFE having a maximum peak temperature of 338° C. or lower in an endothermic curve of a crystal melting curve determined using a differential scanning calorimeter and a high melting point PTFE having a maximum peak temperature of 342° C. or higher in the endothermic curve of the crystal melting curve determined using the differential scanning calorimeter.

The low melting point PTFE is in the form of powder produced by emulsion polymerization and has the aforementioned maximum endothermic peak temperature (crystalline melting point), a permittivity (ε) of 2.08 to 2.2, and a dissipation factor (tan δ) of 1.9×10⁻⁴ to 4.0×10⁻⁴. Examples of commercially available products thereof include Polyflon fine powder series F201, F203, F205, F301, and F302 available from Daikin Industries, Ltd.; CD090 and CD076 available from AGC Inc.; and TF6C, TF62, and TF40 available from DuPont.

The high melting point PTFE powder is also in the form of powder produced by emulsion polymerization and has the aforementioned maximum endothermic peak temperature (crystalline melting point), a permittivity (ε) of 2.0 to 2.1, and a dissipation factor (tan δ) of 1.6×10⁻⁴ to 2.2×10⁻⁴, i.e., its parameters are low on the whole. Examples of commercially available products thereof include Polyflon fine powder series F104 and F106 available from Daikin Industries, Ltd.; CD1, CD141, and CD123 available from AGC Inc.; and TF6 and TF65 available from DuPont.

A powder formed by secondary agglomeration of both of these PTFE polymer particulates commonly preferably has an average particle size of 250 to 2000 μm. In particular, a granulated powder obtainable by granulation with a solvent is preferred to improve the fluidity upon mold filling in pre-molding.

The PTFE in the form of powder satisfying the aforementioned parameters is obtainable by a conventional production method. For example, this powder may be produced according to the production method disclosed in WO 2015/080291 or WO 2012/086710.

The powdery PTFE used preferably has a primary particle size of 0.05 to 10 μm. Using this PTFE can advantageously lead to excellent moldability and excellent dispersibility. The primary particle size herein refers to a value determined in conformity with ASTM D4895.

The powdery PTFE preferably contains 50% by mass or more, more preferably 80% by mass or more of a polytetrafluoroethylene resin having a secondary particle size of 500 μm or greater. The presence of PTFE having a secondary particle size of 500 μm or greater in an amount within this range can advantageously lead to production of a high strength mixture sheet.

Using PTFE having a secondary particle size of 500 μm or greater can lead to a mixture sheet having a lower resistance and better toughness.

The lower limit of the secondary particle size is more preferably 300 μm, still more preferably 350 μm. The upper limit of the secondary particle size is more preferably 700 μm or smaller, still more preferably 600 μm or smaller. The secondary particle size can be determined by sieving, for example.

To provide a fluororesin sheet having a higher strength and excellent uniformity, the powdery PTFE preferably has an average primary particle size of 50 nm or greater, more preferably 100 nm or greater, still more preferably 150 nm or greater, particularly preferably 200 nm or greater.

The greater the average primary particle size of the PTFE is, the less the paste extrusion pressure increases and the better the moldability is in paste extrusion of the powder. The upper limit thereof may be, but is not limited to, 500 nm. In terms of productivity in the polymerization step, the average primary particle size is preferably 350 nm.

The primary particle size can be determined as follows. Specifically, using a PTFE aqueous dispersion obtained by polymerization and adjusted to have a polymer concentration of 0.22% by mass, the transmittance of 550-nm incident light relative to the unit length of the aqueous dispersion is measured. The Feret diameters in a transmission electron microscopic image are then measured and the average primary particle size is determined therefrom. A calibration curve is obtained from these values. The transmittance of the target aqueous dispersion is measured and, using the calibration curve, the average primary particle size is determined.

The PTFE used in the disclosure may have a core-shell structure. The PTFE having a core-shell structure may be, for example, modified polytetrafluoroethylene having in a particle the core of high molecular weight polytetrafluoroethylene and the shell of lower molecular weight polytetrafluoroethylene or modified polytetrafluoroethylene. An example of this modified polytetrafluoroethylene may be polytetrafluoroethylene disclosed in JP 2005-527652 T.

The perfluorinated fluororesin contains preferably less than 200, more preferably less than 120, still more preferably less than 70 unstable end groups per 1×10⁶ carbon atoms. The lower limit is not limited. The number of unstable end groups within this range can lead to better electric properties.

The unstable end groups preferably include at least one selected from the group consisting of —COF, —COOH, —COOCH₃, —CONH₂, and —CH₂OH present at a main chain end of the perfluorinated fluororesin. These may be associated with water.

The number of unstable end groups can be reduced by fluorination treatment on the perfluorinated fluororesin, for example.

The fluorination treatment can be performed by a known method, such as contact between a fluororesin without fluorination treatment and a fluorine-containing compound.

Examples of the fluorine-containing compound include fluorine radical sources that generate fluorine radicals under fluorination treatment conditions, such as F₂ gas, CoF₃, AgF₂, UF₆, OF₂, N₂F₂, CF₃OF, and halogen fluorides, e.g., IF₅ and ClF₃.

The number of unstable end groups can be determined by infrared spectroscopy. Specifically, the perfluorinated fluororesin is melt-extrusion-molded to form a film having a thickness of 0.25 to 0.3 mm. This film is analyzed by Fourier transform infrared spectroscopy to provide an infrared absorption spectrum of the copolymer, and the difference spectrum is obtained between the resulting spectrum and a base spectrum without unstable end groups owing to complete fluorination treatment. Based on the absorption peaks of specific unstable end groups appearing in this difference spectrum, the number N of unstable end groups per 10⁶ carbon atoms in the copolymer is calculated based on the following formula (A).

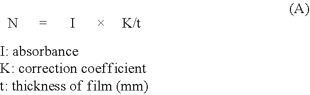

The perfluorinated fluororesin preferably has a melting point of 240° C. to 340° C. This enables easy melt kneading.

The melting point of the perfluorinated fluororesin is more preferably 318° C. or lower, still more preferably 315° C. or lower, while more preferably 245° C. or higher, still more preferably 250° C. or higher.

The melting point of the perfluorinated fluororesin is the temperature corresponding to the maximum value on a heat-of-fusion curve with a temperature-increasing rate of 10° C./min using a differential scanning calorimeter (DSC).

The perfluorinated fluororesin preferably has a melt flow rate (MFR) at 372° C. of 0.1 to 100 g/10 min. This enables easy melt kneading.

The MFR is more preferably 0.5 g/10 min or higher, still more preferably 1.5 g/10 min or higher, while more preferably 80 g/10 min or lower, still more preferably 40 g/10 min or lower.

The MFR is a value obtained as the mass (g/10 min) of a polymer flowing out of a nozzle (inner diameter: 2 mm, length: 8 mm) per 10 minutes at a temperature of 372° C. and a load of 5 kg using a melt indexer (available from Yasuda Seiki Seisakusho Ltd.) in conformity with ASTM D1238.

The perfluorinated fluororesin may have any relative permittivity and any dissipation factor. The relative permittivity at 25° C. and a frequency of 10 GHz is preferably 4.5 or lower, more preferably 4.0 or lower, still more preferably 3.5 or lower, particularly preferably 2.5 or lower. The dissipation factor is 0.01 or lower, preferably 0.008 or lower, more preferably 0.005 or lower. The lower limits may be, but are not limited to, 1.0 or higher for the relative permittivity and 0.0001 or higher for the dissipation factor, for example.

The perfluorinated fluororesin is contained in an amount of preferably 60% by mass or more, more preferably 70% by mass or more, still more preferably 80% by mass or more, while preferably 99.9% by mass or less, more preferably 99.0% by mass or less of the composition.

The zinc oxide preferably has an average particle size of 0.01 to 1.0 μm. The zinc oxide having an average particle size within this range is less likely to aggregate and can give good UV laser processibility. The lower limit of the average particle size is more preferably 0.02 μm, still more preferably 0.03 μm. The upper limit of the average particle size is more preferably 0.50 μm, still more preferably 0.30 μm.

The average particle size is a value determined by the laser diffraction scattering method.

The zinc oxide may be surface-treated, and may be, for example, surface-treated with silicon oxide (preferably, silicon oxide hydride), i.e., may have a surface with a coating layer of silicon oxide. The coating layer of silicon oxide can reduce the surface activity of the zinc oxide, which can cause the zinc oxide to less impair the electric properties and thereby leads to better electric properties of the composition of the disclosure.

The amount of the coating layer formed by the silicon oxide is preferably 1% by mass or more, more preferably 2% by mass or more, while preferably 50% by mass or less, more preferably 20% by mass or less of the zinc oxide. Less than 1% by mass of the coating layer may fail to sufficiently reduce the surface activity of the zinc oxide, while more than 50% by mass thereof tends to reduce the dispersibility of the zinc oxide.

The surface treatment on the zinc oxide using the silicon oxide may be performed by the method disclosed in [0085] to [0086] of JP H11-302015 A, for example. Zinc oxide that has been surface-treated by this method may have a solubility in pure water of 2 ppm or less in the form of Zn and may have a solubility in a 0.0005% by mass sulfuric acid aqueous solution of 20 ppm or less in the form of Zn. These solubilities can be determined by atomic absorption spectrometry.

Examples of commercially available products of zinc oxide particles having the above coating layer of silicon oxide include “NANOFINE”® series 50-LP and 100-LP available from Sakai Chemical Industry Co., Ltd.

The zinc oxide provided with the silicon oxide coating layer (first coating layer) formed by the aforementioned method may be further provided with a second coating layer thereon. The second coating layer may be one formed using an oxide of at least one selected from the group consisting of Al, Ti, Zr, Sn, Sb, and a rare-earth element. Examples of the rare-earth element include yttrium, lanthanum, cerium, and neodymium.

The second coating layer may be formed by the method disclosed in [0089] to [0090] of JP H11-302015 A.

The amount of the second coating layer is preferably 0.5% by mass or more, more preferably 2% by mass or more, while preferably 30% by mass or less, more preferably 15% by mass or less of the zinc oxide.

To enhance the dispersibility of the zinc oxide in the perfluorinated fluororesin, formation of the first coating layer or the second coating layer may be followed by surface treatment with organopolysiloxane. The organopolysiloxane used in this surface treatment is commonly in an amount within the range of 1 to 20 parts by mass, preferably 3 to 10 parts by mass relative to the zinc oxide. Preferred examples of the organopolysiloxane include dimethylpolysiloxane and methyl hydrogen polysiloxane.

The amount of the zinc oxide is preferably 0.01% by mass or more, more preferably 0.05% by mass or more, still more preferably 0.1% by mass or more, while preferably 5.0% by mass or less, more preferably 4.0% by mass or less, still more preferably 3.0% by mass or less of the composition.

The composition of the disclosure contains preferably less than 200 masses, more preferably not more than 100 masses, still more preferably not more than 20 masses of the zinc oxide having a size of 10 μm or greater per area of 1 mm² in image analysis by laser microscopic observation. The lower limit is not limited. This range may indicate that the zinc oxide is well dispersed and may lead to particularly good UV laser processibility.

The image analysis by laser microscopic observation is performed by the method to be described in the EXAMPLES below.

The composition of the disclosure may further contain a different component as appropriate. Examples of the different component include additives such as a filler, a cross-linker, an antistatic agent, a heat-resistance stabilizer, a foaming agent, a foam nucleating agent, an antioxidant, a surfactant, a photopolymerization initiator, an anti-wear agent, a surface modifier, a resin other than the modified fluororesin, and a liquid crystal polymer.

The different component preferably includes an inorganic filler other than the zinc oxide. The presence of an inorganic filler can give effects of improving the strength and of reducing the linear expansion coefficient.

The inorganic filler preferably has no ultraviolet absorbency. The phrase “has no ultraviolet absorbency” means that the absorbance of light at a wavelength of 355 nm is lower than 0.1.

The absorbance of light is a value of powder of the inorganic filler packed to have a thickness of 100 μm and is measured using a UV-VIS-NIR spectrophotometer (e.g., “V-770” available from Jasco Corp.) in the reflection geometry.

The inorganic filler may preferably have a relative permittivity at 25° C. and 1 GHz of 5.0 or lower and a dissipation factor at 25° C. and 1 GHz of 0.01 or lower. The lower limits may be, but are not limited to, 1.0 or higher for the relative permittivity and 0.0001 or higher for the dissipation factor.

Specific examples of the inorganic filler include inorganic compounds other than zinc oxide such as silica (e.g., more specifically, crystalline silica, fused silica, spherical fused silica), titanium oxide, zirconium oxide, tin oxide, silicon nitride, silicon carbide, boron nitride, calcium carbonate, calcium silicate, potassium titanate, aluminum nitride, indium oxide, alumina, antimony oxide, cerium oxide, magnesium oxide, iron oxide, and tin-doped indium oxide (ITO). Examples also include minerals such as montmorillonite, talc, mica, boehmite, kaolin, smectite, xonotlite, vermiculite, and sericite. Examples of other inorganic fillers include carbon compounds such as carbon black, acetylene black, ketjen black, and carbon nanotube; metal hydroxides such as aluminum hydroxide and magnesium hydroxide; and glasses such as glass beads, glass flakes, and glass balloons.

One of the inorganic fillers may be used or two or more thereof may be used.

The inorganic filler in the form of powder may be used as it is or may be dispersed in a resin before use.

To achieve excellent effects of improving the strength and of reducing the linear expansion coefficient, the inorganic filler preferably includes at least one selected from the group consisting of silica, boron nitride, talc, and aluminum hydroxide, and is particularly preferably silica.

The inorganic filler may have any shape, and may be in the form of particles, spheres, scales, needles, pillars, cones, pyramids, frustums, polyhedrons, or hollow matters, for example. Preferred among these are the forms of spheres, cubes, bowls, discs, octahedrons, scales, bars, plates, rods, tetrapods, and hollow matters, and more preferred are the forms of spheres, cubes, octahedrons, plates, and hollow matters. With the form of scales or needles, anisotropic filler pieces can be aligned to give higher adhesiveness. Spherical filler pieces are preferred because they have a small surface area and thus have a small influence on the properties of a fluororesin and less increase the viscosity when blended into a liquid.

In the case where the composition of the disclosure contains the inorganic filler, the amount of the inorganic filler is preferably 5% by mass or more, more preferably 10% by mass or more, while preferably 60% by mass or less, more preferably 50% by mass or less, still more preferably 40% by mass or less of the composition.

The inorganic filler preferably has an average particle size of 0.1 to 20 μm. The inorganic filler having an average particle size within this range is less likely to aggregate and can give good surface roughness. The lower limit of the average particle size is more preferably 0.2 μm, still more preferably 0.3 μm. The upper limit of the average particle size is more preferably 5 μm, still more preferably 2 μm.

The average particle size is a value determined by the laser diffraction scattering method.

The inorganic filler preferably has a maximum particle size of 10 μm or smaller. The inorganic filler having a maximum particle size of 10 μm or smaller is less likely to aggregate and can be well dispersed. Also, this inorganic filler allows the resulting fluororesin material to have a low surface roughness. The maximum particle size is more preferably 5 μm or smaller. The maximum particle size is determined from image data of 200 particles randomly selected in a SEM (scanning electron microscope) image using SEM image analysis software.

The inorganic filler may be surface-treated, and may be, for example, surface-treated with a silicone compound. This surface treatment with a silicone compound can reduce the permittivity of the inorganic filler.

The silicone compound used may be, but is not limited to, a conventionally known silicone compound. For example, the silicone compound preferably includes at least one selected from the group consisting of a silane-coupling agent and an organosilazane.

The amount of the silicone compound used for the surface treatment, which is expressed by the amount of the surface-treating agent reacted with the surface of the inorganic filler, is preferably 0.1 to 10 molecules, more preferably 0.3 to 7 molecules per unit surface area (nm²).

The inorganic filler preferably has a specific surface area by the BET method, for example, of 1.0 to 25.0 m²/g, more preferably 1.0 to 10.0 m²/g, still more preferably 2.0 to 6.4 m²/g. The inorganic filler having a specific surface area within this range is preferred because it is less likely to aggregate, and it allows the fluororesin material to have a smooth surface.

The composition of the disclosure has a relative permittivity at 25° C. and 10 GHz of preferably 5.0 or lower, more preferably 4.0 or lower, still more preferably 3.5 or lower. The lower limit thereof may be, but is not limited to, 1.0, for example.

The composition of the disclosure has a dissipation factor at 25° C. and 10 GHz of preferably 0.003 or lower, more preferably 0.002 or lower, still more preferably 0.0015 or lower. The lower limit thereof may be, but is not limited to, 0.0001 or higher, for example.

The composition of the disclosure has an increase in the dissipation factor at 25° C. and 10 GHz of preferably 330% or lower, more preferably 310% or lower, still more preferably 300% or lower relative to the dissipation factor at 25° C. and 10 GHz of the perfluorinated fluororesin. The increase may be 0%.

The composition of the disclosure can suitably be produced by a production method in which the perfluorinated fluororesin and the zinc oxide are melt-kneaded to provide the composition. The disclosure also provides this production method.

The composition of the disclosure may be produced by a method other than the above production method, such as injection molding, blow molding, inflation molding, or vacuum or pressure forming. In the case where the materials are dispersed or dissolved in a solvent, the composition may be produced by paste extrusion or casting.

Any device may be used for the melt-kneading, such as a twin-screw extruder, single-screw extruder, multi-screw extruder, or tandem extruder.

The duration of the melt-kneading is preferably 1 to 1800 seconds, more preferably 60 to 1200 seconds. Too long melt-kneading may impair the fluororesin, while too short melt-kneading may cause insufficient dispersion of the zinc oxide.

The temperature of the melt-kneading is not lower than the melting points of the perfluorinated fluororesin and the zinc oxide, and is preferably 240° C. to 450° C., more preferably 260° C. to 400° C.

The inventors found that the composition of the disclosure containing a perfluorinated fluororesin and zinc oxide has excellent UV laser processibility and excellent electric properties (e.g., low permittivity) as well as good dispersibility. These characteristics are suitable for materials for circuit boards.

In other words, the composition of the disclosure can be suitably used as an insulating material (especially a low dielectric material) of a circuit board.

The “low dielectric material” as used herein means a material having a relative permittivity at 25° C. and 10 GHz of 5.0 or lower and a dissipation factor at 25° C. and 10 GHz of 0.003 or lower; more preferably a material having a relative permittivity at 25° C. and 10 GHz of 4.0 or lower and a dissipation factor at 25° C. and 10 GHz of 0.002 or lower; still more preferably a material having a relative permittivity at 25° C. and 10 GHz of 3.5 or lower and a dissipation factor at 25° C. and 10 GHz of 0.0015 or lower.

The circuit board of the disclosure includes the aforementioned composition of the disclosure and a conductive layer.

The conductive layer used preferably contains a metal.

Examples of the metal include copper, stainless steel, aluminum, iron, silver, gold, and ruthenium. Alloys of any of these may also be used. Preferred is copper.

The copper used may be rolled copper or electrolytic copper.

The metal preferably has a surface having a surface roughness Rz of 2.0 μm or lower on a side facing the composition. This can lead to a good transmission loss when the composition and the metal are joined together.

The surface roughness Rz is more preferably 1.8 μm or lower, still more preferably 1.5 μm or lower, while more preferably 0.3 μm or higher, still more preferably 0.5 μm or higher.

The surface roughness Rz is a value calculated by the method of JIS C6515-1998 (maximum height roughness).

The conductive layer may have a thickness of 2 to 200 μm, preferably 5 to 50 μm, for example.

The conductive layer may be provided on one side of a layer containing the composition of the disclosure or may be provided on both sides thereof.

The layer containing the composition of the disclosure may have a thickness of 1 μm to 1 mm, preferably 1 to 500 μm, for example. The thickness is more preferably 150 μm or smaller, still more preferably 100 μm or smaller.

The circuit board of the disclosure may further include a resin other than the perfluorinated fluororesin stacked on the composition of the disclosure and the conductive layer.

The resin other than the perfluorinated fluororesin suitably used may be a thermosetting resin.

The thermosetting resin preferably includes at least one selected from the group consisting of polyimide, modified polyimide, epoxy resin, and thermosetting modified polyphenylene ether, and is more preferably epoxy resin, modified polyimide, or thermosetting modified polyphenylene ether, still more preferably epoxy resin or thermosetting modified polyphenylene ether.

The resin other than the perfluorinated fluororesin may be a resin other than the thermosetting resin.

The resin other than the thermosetting resin preferably includes at least one selected from the group consisting of a liquid crystal polymer, polyphenylene ether, thermoplastic modified polyphenylene ether, a cycloolefin polymer, a cycloolefin copolymer, polystyrene, and syndiotactic polystyrene.

The resin other than the perfluorinated fluororesin has a thickness of preferably 5 μm or greater, more preferably 10 μm or greater, while preferably 2000 μm or smaller, more preferably 1500 μm or smaller.

The resin other than the perfluorinated fluororesin is preferably in the form of sheet having a substantially constant thickness. In the case where the perfluorinated fluororesin includes portions having different thicknesses, the thickness refers to the average of the thicknesses measured at the points defined by dividing the perfluorinated fluororesin into 10 equal parts in the longitudinal direction.

The circuit board of the disclosure has a thickness of preferably 20 μm or greater, more preferably 30 μm or greater, while preferably 5000 μm or smaller, more preferably 3000 μm or smaller.

The circuit board of the disclosure is preferably in the form of sheet having a substantially constant thickness. In the case where the board includes portions having different thicknesses, the thickness refers to the average of the thicknesses measured at the points defined by dividing the board into 10 equal parts in the longitudinal direction.

The circuit board of the disclosure is suitably used as a printed circuit board, a multilayer circuit board (multilayer board), or a high frequency board.

The high frequency circuit board is a circuit board that is operable in a high frequency band. The high frequency band may be a band of 1 GHz or higher, preferably a band of 3 GHz or higher, more preferably a band of 5 GHz or higher. The upper limit may be, but is not limited to, a band of 100 GHz or lower.

The circuit board of the disclosure is preferably in the form of a sheet. The circuit board of the disclosure preferably has a thickness of 10 to 3500 μm, more preferably 20 to 3000 μm.

The disclosure also relates to a fluororesin sheet obtainable by forming the aforementioned composition of the disclosure into a sheet. The sheet may be formed by any method, such as paste extrusion or powder rolling. The fluororesin sheet of the disclosure can suitably be produced by a production method in which the aforementioned composition of the disclosure is paste-extruded or powder-rolled to provide the fluororesin sheet. The disclosure also provides this production method.

As described above, the perfluorinated fluororesin used for the fluororesin sheet of the disclosure is preferably a non-melt-moldable perfluorinated fluororesin. In the case of using this perfluorinated fluororesin, this perfluorinated fluororesin is preferably molded into a sheet by forming powdery PTFE, which is a material, into fibrils for molding.

Specific methods of paste extrusion and powder rolling are not limited, and common methods thereof are described below.

### (Paste Extrusion)

The method for producing a fluororesin sheet may include: a step (1a) of mixing a perfluorinated fluororesin (preferably PTFE powder) obtained from a hydrocarbon surfactant, zinc oxide, and an extrusion aid; a step (1b) of paste extruding the resulting mixture; a step (1c) of rolling the extrudate obtained by the extrusion; a step (1d) of drying the rolled sheet; and a step (1e) of firing the dried sheet to provide a molded article.

The paste extrusion may alternatively be performed by mixing the PTFE powder with conventionally known additives such as a pigment and a filler.

The extrusion aid used may be, but is not limited to, a known one. An example thereof may be a hydrocarbon oil.

### (Powder Rolling)

The fluororesin sheet may also be formed by powder rolling. The powder rolling is a method in which a shearing force is applied to resin powder to form it into fibrils, which are then formed into a sheet. The method may subsequently include a step of firing the sheet to provide a molded article.

More specifically, the sheet may be produced by a production method including:
a step (1) of applying a shearing force while mixing a material composition containing a perfluorinated fluororesin and zinc oxide;
a step (2) of molding the mixture obtained in the step (1) into a bulk; and
a step (3) of rolling the bulk mixture obtained in the step (2) into a sheet.

In the case of producing a sheet by this powder rolling, preferably, only a perfluorinated fluororesin and zinc oxide are mixed for molding.

The disclosure (1) relates to a composition containing: a perfluorinated fluororesin; and zinc oxide (hereinafter, also referred to as the “composition of the disclosure”).

The disclosure (2) relates to the composition of the disclosure (1), wherein the zinc oxide is contained in an amount of 0.01 to 5.0% by mass of the composition.

The disclosure (3) relates to the composition of the disclosure (1) or (2), wherein the zinc oxide has an average particle size of 0.01 to 1.0 μm.

The disclosure (4) relates to a composition combined with any one of the disclosures (1) to (3), wherein the composition contains less than 200 masses of the zinc oxide having a size of 10 μm or greater per area of 1 mm² in image analysis by laser microscopic observation.

The disclosure (5) relates to a composition combined with any one of the disclosures (1) to (4), wherein the perfluorinated fluororesin contains less than 200 unstable end groups per 1×10⁶ carbon atoms, the unstable end groups include at least one selected from the group consisting of —COF, —COOH, —COOCH₃, —CONH₂, and —CH₂OH present at a main chain end of the perfluorinated fluororesin.

The disclosure (6) relates to a composition combined with any one of the disclosures (1) to (5), wherein the perfluorinated fluororesin includes at least one selected from the group consisting of polytetrafluoroethylene, a tetrafluoroethylene/perfluoro(alkyl vinyl ether) copolymer, and a tetrafluoroethylene/hexafluoropropylene copolymer.

The disclosure (7) relates to a composition combined with any one of the disclosures (1) to (6), wherein the perfluorinated fluororesin has a melting point of 240° C. to 340° C.

The disclosure (8) relates to a composition combined with any one of the disclosures (1) to (7) and containing an inorganic filler other than the zinc oxide.

The disclosure (9) relates to the composition of the disclosure (8), wherein the inorganic filler has no ultraviolet absorbency.

The disclosure (10) relates to the composition of the disclosure (8) or (9), wherein the inorganic filler has a relative permittivity at 25° C. and 1 GHz of 5.0 or lower and a dissipation factor at 25° C. and 1 GHz of 0.01 or lower.

The disclosure (11) relates to a composition combined with any one of the disclosures (8) to (10), wherein the inorganic filler is contained in an amount of 10 to 60% by mass of the composition.

The disclosure (12) relates to a composition combined with any one of the disclosures (1) to (11), wherein the composition has a dissipation factor at 25° C. and 10 GHz of 0.003 or lower.

The disclosure (13) relates to a composition combined with any one of the disclosures (1) to (12), wherein the composition has an increase in the dissipation factor at 25° C. and 10 GHz of 330% or lower relative to a dissipation factor at 25° C. and 10 GHz of the perfluorinated fluororesin.

The disclosure (14) relates to a composition combined with any one of the disclosures (1) to (13), which is used for an insulating material of a circuit board.

The disclosure (15) relates to a composition combined with any one of the disclosures (1) to (14), wherein the insulating material of a circuit board is a low dielectric material.

The disclosure (16) relates to a circuit board including: a composition combined with any one of the disclosures (1) to (15) and a conductive layer (hereinafter, also referred to as the “circuit board of the disclosure”).

The disclosure (17) relates to the circuit board of the disclosure (16), wherein the conductive layer contains metal.

The disclosure (18) relates to the circuit board of the disclosure (17), wherein the metal has a surface having a surface roughness Rz of 2.0 μm or lower on a side facing the composition.

The disclosure (19) relates to the circuit board of the disclosure (17) or (18), wherein the metal is copper.

The disclosure (20) relates to the circuit board of the disclosure (19), wherein the copper is rolled copper or electrolytic copper.

The disclosure (21) relates to a circuit board combined with any one of the disclosures (16) to (20), which is a printed circuit board, multilayer circuit board, or high frequency board.

The disclosure (22) relates to a method for producing a composition combined with any one of the disclosures (1) to (15), including: melt-kneading the perfluorinated fluororesin and the zinc oxide to provide the composition (hereinafter, also referred to as the “production method of the disclosure”).

The disclosure (23) relates to a method for producing a fluororesin sheet containing a composition combined with any one of the disclosures (1) to (15), the method including: paste-extruding or powder-rolling the composition to provide the fluororesin sheet (hereinafter, also referred to as the “fluororesin sheet production method of the disclosure”).

### EXAMPLES

The disclosure is described in more detail below with reference to examples, but is not limited to these examples.

The materials used in the examples are as follows.

### (Fluororesin)

PFA (1): (TFE/PAVE (% by mass): 94.6/5.4, amount of fluorine-containing monomer: 100 mol %, melting point: 303° C., MFR: 14 g/10 min, relative permittivity (25° C., 10 GHz): 2.1, dissipation factor (25° C., 10 GHz): 0.00031, number of unstable end groups: 0 per 1×10⁶ carbon atoms, types of unstable end groups: —COF and —COOH, as well as —COOH, —CH₂OH, —CONH₂, and —COOCH₃ associated with water)

PFA (2): (TFE/PAVE (% by mass): 94.6/5.4, amount of fluorine-containing monomer: 100 mol %, melting point: 303° C., MFR: 14 g/10 min, relative permittivity (25° C., 10 GHz): 2.1, dissipation factor (25° C., 10 GHz): 0.0010, number of unstable end groups: 178 per 1×10⁶ carbon atoms, types of unstable end groups: —COF and —COOH, as well as —COOH, —CH₂OH, —CONH₂, and —COOCH₃ associated with water)

FEP: (TFE/HFP (% by mass): 90/10, amount of fluorine-containing monomer: 100 mol %, melting point: 270° C., MFR: 6 g/10 min, relative permittivity (25° C., 10 GHz): 2.1, dissipation factor (25° C., 10 GHz): 0.00080, number of unstable end groups: 30 per 1×10⁶ carbon atoms, types of unstable end groups: —COF and —COOH, as well as —COOH, —CH₂OH, —CONH₂, and —COOCH₃ associated with water)

### PTFE

ETFE (ethylene/TFE (% by mass): 21/79, amount of fluorine-containing monomer: 52 mol %, relative permittivity (25° C., 10 GHz): 2.36, dissipation factor (25° C., 10 GHz): 0.0716)

### (Inorganic Filler)

Zinc oxide (1) (average particle size: 150 nm, surface treatment: not performed)

Zinc oxide (2) (average particle size: 35 nm, surface treatment: silane treatment (treated with silicon oxide having average particle size of 0.02 μm), amount of coating layer formed from silicon oxide: 4.9% by mass)

Titanium oxide: (average particle size: 150 nm, surface treatment: not performed)

Silica (no ultraviolet absorbency (absorbance of light at a wavelength of 355 nm: lower than 0.1), relative permittivity (25° C., 1 GHz): 2.8, dissipation factor (25° C., 1 GHz): 0.001, average particle size: 0.5 μm, specific surface area: 6.1 m²/g, surface treatment: not performed)

### Examples 1 to 7 and Comparative Examples 1 to 4

A fluororesin and an inorganic filler were melt-kneaded (duration: 600 seconds, temperature: 350° C.) at the ratio (% by mass) shown in Table 1 using a Labo Plastomill mixer, whereby a composition was obtained.

The resulting composition was extruded at the processing temperature shown in Table 1, whereby a sheet having the thickness shown in Table 1 was obtained.

In Example 7, the sheet obtained in Example 1 and copper foil (electrolytic copper, thickness: 9 μm, surface roughness Rz on a side to be joined to the sheet: 1.5 μm) were stacked and pressed at a heating temperature of 320° C. and a pressure of 15 kN for five minutes. Thereby, a joined article including the sheet joined to one side of the copper foil was obtained.

### Example 8

PTFE and zinc oxide (1) at the ratio (% by mass) shown in Table 1 as well as 22 parts of the aid IP2028 were mixed and stirred at room temperature. The mixture was aged for 16 hours and paste-extruded at 40° C. through a die (thickness: 1 mm, width 100 mm) with a flat outlet, whereby a sheet was obtained. The resulting sheet was rolled to provide a sheet having the thickness shown in Table 1, which was then fired at 360° C. for 20 minutes. Thereby, a sheet for evaluation was obtained.

### (UV Laser Processibility)

The above sheet was irradiated with a UV laser under the following conditions and the state after the irradiation was evaluated. In Example 7, the UV laser was applied to the sheet in the joined article.
Pore size: 100 μm
Output: 2 W
Number of shots repeated: 7

The evaluation was based on the following criteria.
Excellent: pierced and not carbonized
Good: pierced but carbonized
Poor: not pierced

### (Number of Masses of Zinc Oxide (Image Analysis by Laser Microscopic Observation), Additive Dispersibility)

The number of masses of zinc oxide having a size of 10 μm or greater per area of 1 mm² was evaluated by the following method.

A sample (sheet) was cut out with a razor and the cross section was observed with a laser microscope. For the number of masses of zinc oxide, the number of masses per area of 0.069 mm² (length 0.23 mm, width 0.3 mm) in an image obtained at a magnification of 50 was counted, which was then converted into the number of masses per area of 1 mm².

The dispersibility of the additive (zinc oxide) was evaluated based on the following criteria.
Excellent: less than 20 masses of zinc oxide having a size of 10 μm or greater in image analysis by laser microscopic observation
Good: Not less than 20 but less than 200 masses of zinc oxide having a size of 10 μm or greater in image analysis by laser microscopic observation; evaluated as uniform in visual observation
Poor: Not less than 200 masses of zinc oxide having a size of 10 μm or greater in image analysis by laser microscopic observation; evaluated as nonuniform in visual observation

In Comparative Example 3 where titanium oxide was added instead of zinc oxide, the same evaluation was performed for titanium oxide.

### (Relative Permittivity (Dk) and Dissipation Factor (Df))

The sheets of Example 1, Example 2, Comparative Example 3, and Comparative Example 4 were subjected to measurement of Dk and Df at 25° C. and 10 GHz using a split cylinder permittivity and dissipation factor measurement system (available from EM labs, Inc.). With each of the measured Df values, the increase relative to the Df value of the resin alone (Df before adding inorganic filler) was calculated by the following formula.

Consequently, the following results were obtained.

In Example 1, Dk was 2.06, Df was 0.00084, and the Df increase was 171%.

In Example 2, Dk was 2.02, Df was 0.00122, and the Df increase was 294%.

In Comparative Example 3, Dk was 2.12, Df was 0.00150, and the Df increase was 384%.

In Comparative Example 4, Dk was 2.22, Df was 0.0132, and the Df increase was <1%.

Although the Df increase was low, the Df value was high in Comparative Example 4.

### [Formula for Calculating Increase]

$$( Increase / \% ) = ( Df 2 - Df 1 ) \times 100 / Df 1$$

$$Df 2 : Df / - after adding inorganic filler$$

$$Df 1 : Df / - before adding inorganic filler$$

TABLE 1

| | | Surface treatment | Example 1 | Example 2 | Example 3 | Example 4 | Example 5 | Example 6 |
|---|---|---|---|---|---|---|---|---|
| Composition | PFA (1) | — | 99 | 98 | 99 | 89 | | |
| (mass %) | PFA (2) | — | | | | | 99 | |
| | FEP | — | | | | | | 98 |
| | PTFE | — | | | | | | |
| | ETFE | — | | | | | | |
| | Zinc oxide (1) particle size 150 nm | Not performed | 1 | 2 | | 1 | 1 | 2 |
| | Zinc oxide (2) particle size 35 nm | Silane treatment | | | 1 | | | |
| | Titanium oxide particle size 150 nm | Not performed | | | | | | |
| | Silica | — | | | | 10 | | |

| | | | | | | | |
|---|---|---|---|---|---|---|---|
| Copper clad laminate (one side, | — | No | No | No | No | No | No |
| copper foil thickness 18 μm) | | | | | | | |
| Processing temperature/° C. | — | 350 | 350 | 350 | 350 | 350 | 300 |
| Thickness/μm | — | 100 | 100 | 100 | 100 | 100 | 100 |
| UV laser processibility | — | Excellent | Excellent | Excellent | Excellent | Excellent | Excellent |
| Additive dispersibility | — | Good | Good | Excellent | Good | Good | Good |

| | | | | Comparative | Comparative | Comparative | Comparative |
|---|---|---|---|---|---|---|---|
| | | Example 7 | Example 8 | Example 1 | Example 2 | Example 3 | Example 4 |
| Composition | PFA (1) | 99 | | 100 | 90 | 98 | |
| (mass %) | PFA (2) | | | | | | |
| | FEP | | | | | | |
| | PTFE | | 99 | | | | |
| | ETFE | | | | | | 98 |
| | Zinc oxide (1) particle size 150 nm | 1 | 1 | | | | 2 |
| | Zinc oxide (2) particle size 35 nm | | | | | | |
| | Titanium oxide particle size 150 nm | | | | | 2 | |
| | Silica | | | | 10 | | |

| | | | | | | |
|---|---|---|---|---|---|---|
| Copper clad laminate (one side, | Yes | No | No | No | No | No |
| copper foil thickness 18 μm) | | | | | | |
| Processing temperature/° C. | 350 | 40 | 350 | 350 | 350 | 310 |
| Thickness/μm | 100 | 100 | 100 | 100 | 100 | 100 |
| UV laser processibility | Excellent | Excellent | Poor | Poor | Excellent | Excellent |
| Additive dispersibility | Good | Good | — | — | Excellent | Good |

1. A composition used for an insulating material of a circuit board, which comprises:
a perfluorinated fluororesin; and
zinc oxide,
wherein the perfluorinated fluororesin contains a fluorine-containing monomer in an amount of 90 mol % or more.

2. The composition according to claim 1,
wherein the zinc oxide is contained in an amount of 0.01 to 5.0% by mass of the composition.

3. The composition according to claim 1,
wherein the zinc oxide has an average particle size of 0.01 to 1.0 μm.

4. The composition according to claim 1,
wherein the composition contains less than 200 masses of the zinc oxide having a size of 10 μm or greater per area of 1 mm² in image analysis by laser microscopic observation.

5. The composition according to claim 1,
wherein the perfluorinated fluororesin contains less than 200 unstable end groups per 1×10⁶ carbon atoms,
the unstable end groups include at least one selected from the group consisting of —COF, —COOH, —COOCH₃, —CONH₂, and —CH₂OH present at a main chain end of the perfluorinated fluororesin.

6. The composition according to claim 1,
wherein the perfluorinated fluororesin includes at least one selected from the group consisting of polytetrafluoroethylene, a tetrafluoroethylene/perfluoro(alkyl vinyl ether) copolymer, and a tetrafluoroethylene/hexafluoropropylene copolymer.

7. The composition according to claim 1,
wherein the perfluorinated fluororesin has a melting point of 240° C. to 340° C.

8. The composition according to claim 1, further comprising an inorganic filler other than the zinc oxide.

9. The composition according to claim 8,
wherein the inorganic filler has no ultraviolet absorbency.

10. The composition according to claim 8,
wherein the inorganic filler has a relative permittivity at 25° C. and 1 GHz of 5.0 or lower and a dissipation factor at 25° C. and 1 GHz of 0.01 or lower.

11. The composition according to claim 8,
wherein the inorganic filler is contained in an amount of 10 to 60% by mass of the composition.

12. The composition according to claim 1,
wherein the composition has a dissipation factor at 25° C. and 10 GHz of 0.003 or lower.

13. The composition according to claim 1,
wherein the composition has an increase in the dissipation factor at 25° C. and 10 GHz of 330% or lower relative to a dissipation factor at 25° C. and 10 GHz of the perfluorinated fluororesin.

14. The composition according to claim 1,
wherein the insulating material of a circuit board is a low dielectric material.

15. A circuit board comprising:
the composition according to claim 1; and
a conductive layer.

16. The circuit board according to claim 15,
wherein the conductive layer comprises metal.

17. The circuit board according to claim 16,
wherein the metal is copper.

18. The circuit board according to claim 15, which is a printed circuit board, multilayer circuit board, or high frequency board.

19. A method for producing the composition according to claim 1, the method comprising:
melt-kneading the perfluorinated fluororesin and the zinc oxide to provide the composition.

20. A method for producing a fluororesin sheet containing the composition according to claim 1, the method comprising:
paste-extruding or powder-rolling the composition to provide the fluororesin sheet.
